(19) United States
(12) Patent Application Publication
(10) Pub. No.: US 2026/0074725 A1
(43) Pub. Date: Mar. 12, 2026

(54) Method and Device for Converting an Analog Input Signal into a Digital Output Signal

(71) Applicant: Siemens Aktiengesellschaft, Muenchen (DE)

(72) Inventors: Alexander HELMDACH, Chemnitz (DE); Dirk PROCHASKA, Chemintz (DE); Robert WEIKERT, Burggriesbach (DE); Gunter GRIESSBACH, Dresden (DE); Oliver RAAB, Ortenburg (DE)

(21) Appl. No.: 19/257,618

(22) Filed: Jul. 2, 2025

(30) Foreign Application Priority Data
Jul. 4, 2024 (EP) 24186430

(51) Int. Cl. H04B 1/10; H04L 27/00; H04L 27/06; H04L 27/22

(52) U.S. Cl. CPC H04B 1/1027; H04L 27/0008; H04L 27/06; H04L 27/22

(57) ABSTRACT

Method and device for converting an analog input signal into a digital output signal, wherein the analog input signal is supplied to be converted to the input side of an amplitude modulator with carrier suppression to obtain a carrierless amplitude-modulated signal, an adder adds a sinusoidal carrier signal offset by 90° to the amplitude-modulated signal output by the amplitude modulator to obtain a phase-modulated signal, the phase-modulated signal is supplied to a limiter that is used to suppress interference amplitude modulation in the phase-modulated signal, and the signal output by the limiter is supplied to a demodulator and sampled therein with at least one sampling clock signal, where the phase position of the at least one sampling clock signal is dynamically altered to achieve a higher resolution.

### BACKGROUND OF THE INVENTION

### 1. Field of the Invention

The invention relates to a device and method for converting an analog input signal into a digital output signal, where the method comprises supplying feeding the analog input signal to be converted to the input side of an amplitude modulator with carrier suppression to obtain a carrierless amplitude-modulated signal, using an adder to add a preferably sinusoidal carrier signal offset by 90° to the amplitude-modulated signal output by the amplitude modulator to obtain a phase-modulated signal, supplying the phase-modulated signal to a limiter that is used to suppress interference amplitude modulation in the phase-modulated signal, and supplying the signal output by the limiter to a demodulator and sampling it therein with at least one sampling clock signal.

### 2. Description of the Related Art

An analog-digital converter is used to convert an analog input variable into a digital signal. Conventional analog-digital converters are, e.g., the SAR converter (successive-approximation converter) and the sigma-delta converter. Both converter types have their disadvantages, resulting from DC voltage errors in the analog input signal. With the sigma-delta converter, a comparison signal is formed and subjected to analog filtering, i.e., is reconstructed. Jumps in the analog input signal can thus lead to transient oscillation errors. In order to realize galvanically isolated inputs, fully separate A/D converters are required for each input channel. The problem with the SAR converter is that significant quantization noise occurs. Moreover, scaling requires a very precise amplitude reference that is temperature- and age-stable. An upper cut-off frequency for the components used in the A/C converter restricts usability at higher signal frequencies.

Chopper amplifiers are used to resolve the aforementioned problems. Galvanic isolation is realized by separate converters with their own potential. By contrast, it is not currently possible to shift the upper cut-off frequency. Precise, stable references for scaling are also complex and expensive.

EP 3 624 334 A1 discloses a developed device for converting an analog input signal into a digital output signal. This publication specifically relates to an analog-digital converter (A/D converter), which is based on the difference in the phase position of a signal modulated to the input voltage being measured in comparison to a reference signal. The analog-digital converter disclosed in EP 3 624 334 A1 can also be referred to as a phase modulation converter.

The phase modulation converter of EP 3 624 334 A1 comprises an amplitude modulator with carrier suppression for providing a carrierless amplitude-modulated signal. The amplitude modulator has a signal input, to which an analog input signal to be converted can be supplied. There is also an adder, to which the carrierless amplitude-modulated signal output by the amplitude modulator is supplied and which is set up to add a carrier signal offset by 90° to this and to provide a phase-modulated signal. There is also a limiter, to which the phase-modulated signal output by the adder is supplied and which is designed to suppress interference amplitude modulation in the phase-modulated signal.

The resultant output signal of the limiter has an amplitude that is 0 or 1. It can also be said that a digital signal is present in the amplitude. The length of these pulses is continuous in value depending on the selected carrier frequency. The information is contained in the length of the rectangular pulses. The limiter's output signal carries the modulation in zero crossings at different times in comparison to the 90° carrier signal. Reference is also made in this context to the figures of EP 3 624 334 A1, particularly FIGS. 5 to 8 contained therein and the accompanying description, which explains the principle in more detail.

The signal output by the limiter, which is also referred to there in short as the limited signal, can then be sampled, where the sampling must be fast enough to detect zero crossings (sampling theory).

The conventional phase modulation of EP 3 624 334 A1 has proved itself in principle. However, it is sometimes necessary to achieve high resolutions.

For high accuracy with the phase modulation converter, it is generally recommended to have the greatest possible difference between the sampling rate fₛₐₘₚₗₑ of the modulated input signal, i.e., of the limited signal to be sampled, in comparison to the clock of the amplitude modulator, i.e., of the modulator frequency. This frequency advantageously corresponds to the frequency of the reference signal, which is used for comparison and can also be referred to as f_{reference}.

$$Rule :$$

$$N [ bit ] = {log}_{2} ( 90 ° / 360 ° * {f}_{sample} / {f}_{reference} ) .$$

It would theoretically be conceivable to reduce or minimize f_{reference} for higher accuracy. However, this would have the crucial disadvantage that filter components, which are used, for example, to filter harmonic waves from the spectrum of rectangular signals used for the phase modulation converter, which can be used to clock the modulator or the reference signal, would then be much larger. Additionally, the data rate of the phase modulation converter depends on the modulator frequency and thus in particular on the frequency of the reference signal. The phase modulation converter supplies one new value for each full cycle of the reference signal. Reducing the frequency of the reference signal would thus also make the phase modulation converter correspondingly slower.

With regard to the second control variable (the pure sampling frequency, i.e., the frequency of the sampling clock signal), this cannot be increased arbitrarily. If, for example, a demodulator based on an FPGA is used, this would, on the one hand, necessitate the use of comparatively fast FPGA families, which are usually very expensive and, on the other, would lead to problems with synthesis and realization, because the timing constraints would no longer be created.

### SUMMARY OF THE INVENTION

In view of the foregoing, it is therefore and object of the present invention to provide a method and a device, which offer improved resolution, while avoiding or at least reducing the stated disadvantages.

This and other objects and advantages are achieved in accordance with the invention by a method in which the phase position of the at least one sampling clock signal is dynamically altered to achieve a higher resolution, particularly in steps of less than 40°, preferably in steps of less than 20°, particularly preferably in steps of less than 10°.

The objects in accordance with the invention are also achieved by a device for converting an analog input signal into a digital output signal for executing the disclosed, comprising an amplitude modulator with carrier suppression, to which an analog input signal to be converted can be supplied to the input side, in order to obtain a carrierless amplitude-modulated signal, an adder for adding a preferably sinusoidal carrier signal offset by 90° to the carrierless amplitude-modulated signal and for obtaining a phase-modulated signal, a limiter, to which the phase-modulated signal is supplied and with which interference amplitude modulation in the phase-modulated signal can be suppressed, and a demodulator, to which the signal output by the limiter is supplied and can be sampled therein with at least one sampling clock signal, wherein the device comprises means for phase position alteration, which are configured to dynamically alter the phase position of the at least one sampling clock signal to achieve a higher resolution, particularly in steps of less than 40°, preferably in steps of less than 20°, particularly preferably in steps of less than 10°.

In other words, the present invention is based on the fundamental idea of deliberately providing a dynamic alteration of the phase position of the sampling clock signal or sampling clock signals used with a phase modulation converter and thereby increasing the resolution. It can also be said that there is a stepping, or active incremental shift, of the phase of the sampling clock signal or (in the case of multiple) sampling clock signals, i.e., the sampling clocks that are used to sample the limited signal. As a result, the effective sampling rate of the phase modulation converter can be increased—compared to a variant without dynamic phase shift.

A considerable advantage of the present invention is that the resolution can be increased by actively shifting the phase or phases, without the effective modulator frequency having to be lowered. This can thus remain high. There is a certain decoupling of the data rate from the modulator frequency, which is advantageous for the hardware wiring.

It has proved particularly advantageous if the modulator frequency is in the range from 1 MHz to 50 MHz. This is also because the filters can be realized in a compact configuration in this frequency range.

In particular, the frequency of the at least one sampling clock signal is at least one order of magnitude higher, preferably two orders of magnitude higher, than the modulator frequency of the amplitude modulator. If multiple sampling clock signals are used for the sampling, then the frequency of all sampling clock signals is preferably at least one order of magnitude higher, preferably two orders of magnitude higher, than the modulator frequency of the amplitude modulator. If multiple sampling clock signals are used for the sampling, then these preferably have the same frequency.

It is also noted that many applications require (capacitive) galvanic isolation. It has been found that such isolation is possible at practically any point on the signal path with a phase modulation converter. If the resolution is increased in the manner in accordance with the invention, then the coupling capacitors and, if necessary, then the downstream filters used for the isolation can be realized in a much smaller and cheaper way than would be the case with a reduction in the modulator frequency.

In an advantageous embodiment, the analog input signal to be converted is supplied to an input of the amplitude modulator with carrier suppression and a particularly rectangular or sinusoidal carrier signal is supplied to another input of the amplitude modulator. The device in accordance with the disclosed embodiments of the invention can be configured accordingly. The carrier signal with a phase shift of 90°, which is added to the amplitude-modulated signal by means of the adder, advantageously has a phase shift of 90° to the carrier signal that is supplied to the amplitude modulator. In particular, the frequency of this carrier signal corresponds to the modulator frequency. Additionally, this carrier signal represents in particular a carrier to be suppressed.

In other words, the phase-modulated signal is formed in particular from the amplitude modulation of the input signal with a carrier and this carrier is suppressed in the amplitude modulator. The carrierless double-sideband signal is added with a 90° carrier. After limiting this signal, a phase-modulated signal is available. The double-sideband signal contains sidebands with identical information in each case. By generating an amplitude-modulated signal with carrier suppression, there is no need for complex compensation of the carrier contained in the amplitude modulation. By adding a new carrier that is rotated by 90° compared to the carrier belonging to the AM signal, a phase-modulated signal with a maximum phase deviation of +/−90° is achieved.

In the case of the amplitude modulator with carrier suppression, this can be, for example, a (digital) switch modulator, for instance, a double push-pull modulator, or even a (digital) ring modulator. The switch modulator preferably comprises or is constituted by at least one in particular digital switch and/or at least one mechanical relay and/or at least one reed relay and/or at least one MEMS switch. In this context, the acronym MEMS stands in the known manner for micro-electromechanical systems.

Advantageously, a differential signal transmission is effected in particular from the output of the amplitude modulator and/or to the output of the limiter or the input of the demodulator. The device in accordance with the disclosed embodiments is configured accordingly. It can also be said that a differential signal transmission is then established, at least starting from the output of the amplitude modulator and in particular at least up to the output of the limiter or up to the demodulator.

The adder can comprise or be formed by at least one operational amplifier. This can in particular be at least one fully differential operational amplifier.

An area overlap between the limited signal and the reference signal is preferably calculated via the demodulator, particularly over multiple cycles. The demodulator can be configured accordingly.

Dynamically altering the phase position of the one sampling clock signal or the multiple sampling clock signals means in particular that the phase position is altered multiple times, recurrently, preferably cyclically, continually, or almost continually.

Due to the active, dynamic phase shift in accordance with the disclosed embodiments of the invention, the phase position of—or in the case of multiple, in particular of all—the sampling clock signals is altered recurrently, for instance, cyclically, in fine steps. The alteration is effected in particular for the runtime, for instance, the program runtime of a demodulator used for the demodulation, which can comprise at least one Field-Programmable Gate Array (FPGA) and/or Application-Specific Integrated Circuit (ASIC) or can be constituted by at least one FPGA and/or ASIC.

Altering the phase position can also be referred to and understood as shifting the phase position. Advantageously, the phase position is always altered by the respective increment in one direction. It can in particular be altered multiple times or recurrently in the same direction and with the same increment. The alteration or “stepping” in accordance with disclosed embodiments of the invention of the phase position of the at least one sampling clock signal can, for example, be effected every couple of microseconds.

In an advantageous embodiment of the method in accordance with the invention, the phase position of the at least one sampling clock signal is dynamically altered in equally large steps and/or in steps of 360°/n in each case, where n is a natural number greater than or equal to 30, particularly greater than or equal to 40, preferably greater than or equal to 50, particularly preferably greater than or equal to 100. The means for phase position alteration of a device according to the invention can be set up accordingly.

In another advantageous embodiment of the method in accordance with the invention, the phase position of the at least one sampling clock signal is altered at multiple successive points in time, in particular separated from each other at equidistant intervals, where there is at least one microsecond between the separated points in time in each case. The time interval between successive points in time of the phase position alteration can, for example, be in the range from 2 to 50 microseconds, preferably in the range from 5 to 50 microseconds. The means for phase position alteration of the device in accordance with disclosed embodiments of the invention can be set up accordingly.

It also possible for the phase position of the at least one sampling clock signal to be altered at least n/m times in steps of 360°/n, where m is a natural number greater than or equal to 1. Here, the means for phase position alteration of the device in accordance with disclosed embodiments of the invention can also be set up in accordance with an alternative embodiment.

It has further proved particularly advantageous if the signal output by the limiter is sampled in the demodulator not only with one, but rather with multiple sampling clock signals that have a phase offset between them. For example, two, three, four, or even more sampling clock signals can be used for the sampling. If multiple sampling clock signals are used, then these advantageously have a constant phase shift between them, i.e., a phase offset. The constant phase shift is thereby advantageously selected based on the number of multiple sampling clock signals. If, for example, four sampling clock signals with a constant phase shift between them are used for the sampling, then these each advantageously have a constant phase shift between them of 90°. In other words, a second sampling clock signal has a constant phase shift of 90° to the first sampling clock signal, a third sampling clock signal has a constant phase shift of 90° to the second sampling clock signal (and of 180° to the first), a fourth sampling clock signal has a constant phase shift of 90° to the third sampling clock signal (and of 270° to the first), and all four sampling clock signals are used together for sampling the limited signal. In other words, the constant phase shift is in particular 360°/m, where m corresponds to the number of clock signals used for the sampling.

If only two sampling clock signals are used that have a constant phase shift between them, then these advantageously have a constant phase shift between them of 180°. With three sampling clock signals, the constant phase shift between two sampling clock signals in each case would advantageously be 120°.

If multiple sampling clock signals are used for the sampling, then these are all advantageously dynamically altered in their phase position in the manner in accordance with disclosed embodiments of the invention. The dynamic, incremental phase position alteration of the multiple sampling clock signals is thereby advantageously effected synchronously in each case and/or in equally large steps, particularly of less than 40°. Additionally, the dynamic, incremental phase position alteration of the multiple sampling clock signals is advantageously effected in such a way that the constant phase shift between the multiple sampling clock signals is maintained.

The use of multiple sampling clock signals within the framework of the disclosed embodiments of the invention offers the advantage that the dynamic phase position alteration only has to cover or pass through a smaller range. It is stated purely as an example that in the case of four sampling clock signals with a constant phase shift between them of 90° in each instance, for which the phase position is dynamically altered simultaneously in each instance, the shift only has to cover a range of 90° rather than the full 360°.

If the phase position of the one or multiple sampling clock signals is altered at least n/m times in steps of 360°/n, then m advantageously corresponds to the number of multiple sampling clock signals that preferably have a constant phase shift between them, which are used together for the sampling, where m can, for example, be 2, 3, 4, or more.

In a further particularly advantageous embodiment of the method, the at least one sampling clock signal is generated from the output signal of a particularly voltage-controlled oscillator, which is an element in a phase-locked loop (PLL), and the dynamic alteration of the phase position of the at least one sampling clock signal is achieved, by dynamically altering the phase position of a feedback signal for the oscillator, which is tapped on the output side of the oscillator and supplied to the oscillator again, particularly on the input side, particularly in steps of less than 40°, preferably in steps of less than 20°, particularly preferably in steps of less than 10°.

By using multiple sampling clock signals, it can further be provided that these are all generated from the output signal of the one in particular voltage-controlled oscillator. The dynamic alteration of the phase position of the feedback signal then results in each case in an alteration of the phase positions of all sampling clock signals synchronously and in equally large steps, which has proven to be a particularly suitable embodiment that is easy to realize.

It can be provided that the oscillator has at least one phase-variable tap and preferably multiple phase-locked taps, where the at least one phase-variable tap allows the 360° phase position of the oscillator to be divided into n steps, where n is a natural number greater than or equal to 30, particularly greater than or equal to 40, preferably greater than or equal to 50, particularly preferably greater than or equal to 100, and where the phase-variable tap is connected to the feedback path of the oscillator, so that a signal coming from the phase-variable tap can be supplied to the oscillator again as a feedback signal, particularly on the input side, and the phase position of the signal coming from the phase-variable tap is dynamically altered in steps of 360°/n.

In an analogous manner, the device in accordance with disclosed embodiments of the invention can be characterized in that it, preferably its demodulator, has a clock generator for generating the at least one sampling clock signal. In an advantageous embodiment, the clock generator has or is formed by at least one, preferably multiple, clock generation module(s). The—or in the case of multiple, the respective—clock generation module can comprise a phase-locked loop with a particularly voltage-controlled oscillator. The oscillator can have at least one phase-variable tap and preferably multiple phase-locked taps, where the at least one phase-variable tap allows the 360° phase position of the oscillator to be divided into n steps, where n is a natural number greater than or equal to 30, particularly greater than or equal to 40, preferably greater than or equal to 50, particularly preferably greater than or equal to 100, and where the phase-variable tap is connected to the feedback path of the oscillator, so that a signal emanating from the phase-variable tap can be supplied to the oscillator again as a feedback signal, particularly on the input side, and the means of phase position alteration can be configured to dynamically alter the phase position of the signal emanating from the phase-variable tap in steps of 360°/n.

In other words, realization can be achieved, for example, by using an oscillator with a phase-variable tap, which facilitates a division of the phase position into fine steps. Purely by way of example, reference is made in this context to FPGAS (field-programmable gate arrays) from the manufacturer Xilinx or AMD, which are available in an embodiment with a mixed-mode clock manager module (MMCM module), which offers a fine division like this of the phase at a phase-variable tap. The corresponding function is also referred to as “finePS,” which stands for “fine phase shift.” This option can be used within the framework of the disclosed embodiments of the present invention, in order to achieve the dynamic, incremental alteration of the phase position(s) and thus the increase in resolution. This is effected in particular by using the phase-variable tap for or as the feedback signal for the oscillator. The applicant knows, for example, of FPGA models from XILINX or AMD that facilitate a division of the phase (finePS) into 56 steps at a corresponding phase-variable tap, i.e., steps of 360°/n where n=56, which has proven suitable within the framework of the present invention. It is stressed, however, that a finer or coarser division is of course also possible and can be used. FPGAs from Lattice Semiconductor are another example, particularly the EPS, ECP5, EPC5-5G series, which likewise facilitate a fine division of the phase, i.e., with up to 300 steps.

The means of phase position alteration of a device in accordance with the disclosed embodiments of the invention can, for example, be formed by or comprise a circuit or logic implemented in particular on an FPGA, which realizes the corresponding control of the dynamic phase shift—or shifts in the case of multiple sampling clock signals—particularly in the embodiment in which a phase-variable tap is connected to the oscillator feedback path. Such a control logic can also be used to tap/reset an integrator of the device in accordance with disclosed embodiments of the invention.

It is also advantageous that the signal output by the limiter that is supplied to the demodulator is compared in the demodulator in an XOR module bit-by-bit to a reference signal after sampling with the one or more sampling clock signals, and the output signal of the XOR module is integrated. It is also preferable that integration is maintained in each case until the dynamic alteration of the phase position is effected over an angle range of 360°/m, where m is a natural number preferably corresponding to the number of sampling clock signals. The device in accordance with disclosed embodiments of the invention, particularly an FPGA of this, can be set up accordingly.

In an analogous manner, the device in accordance with disclosed embodiments of the invention can be characterized in that it, particularly its demodulator, comprises at least one XOR module and at least one integrator downstream of the XOR module. The XOR module can comprise an XOR gate or be constituted by such.

In the case of the reference signal, this can be in particular a signal that is or has been generated in or by the demodulator, particularly using the at least one clock generator of the demodulator. The reference signal is likewise advantageously—in a fully analogous manner to the limited signal and parallel to this—sampled with the at least one sampling clock signal, where the reference signal is advantageously sampled with the one or more sampling clock signals synchronously with the sampling of the limited signal with the one or more sampling clock signals.

It has further proven advantageous for sampling values, which are present as a result of the sampling of the signal output by the limiter with the at least one sampling clock signal, to be buffered. At least one buffer, for instance, at least one FIFO buffer, can be present for this, for example. It can also be provided that multiple signal sampling values can be output in each case by the buffer at a lower frequency in comparison to the frequency of the at least one sampling clock signal. In this instance, the buffer has an output with a higher bit width than its input. It is stated purely as an example that a slower internal clock, which is used for synchronizing with the buffer, has a frequency of 32 MHz, while the sampling clock signal or signals for sampling the signal output by the limiter are 256 MHz. Then the used buffer(s) advantageously have an input width of one bit and an output width of 8 bits. Other configurations and resulting bit ratios of the input and output of the used buffers are of course also possible.

In a fully analogous manner, reference sampling values, which are present or obtained because of a (particularly parallel or synchronous) sampling of a reference signal with the at least one sampling clock signal, can be buffered in at least one reference buffer. The at least one reference buffer can also be a FIFO buffer. Multiple reference sampling values are then advantageously output in each case by the at least one reference buffer at a lower frequency in comparison to the frequency of the at least one sampling clock signal. In other words, a slow internal clock domain is also used for the reference signal in a preferred embodiment, which is used for synchronizing down or synchronizing with the reference buffer(s).

Signal sampling values and reference e sampling values are advantageously synchronized to the same slower internal clock domain.

If multiple, for example, four sampling clock signals with a constant phase shift between them are used for the sampling, a number of buffers, particularly FIFO buffers, advantageously corresponding to the number of sampling clock signals is present, namely both for the limited signal and for the reference signal. If, for example, four sampling clock signals with a constant phase shift between them of 90° in each case are used for the sampling, then eight (FIFO) buffers, four for the limited signal and four for the reference signal, are present, i.e., four signal buffers and four reference buffers. If m corresponds to the number of sampling clock signals used, then 2m buffers (sum of the signal buffers and reference buffers) are thus preferably present. All buffers are then further advantageously connected to the XOR module, in order to transmit values to this for subsequent comparison.

Moreover, both the signal buffer(s) and the reference buffer(s) are preferably connected to the same clock generator and obtain the at least one sampling clock signal from this.

The multiple signal sampling values output by the signal buffer(s) in each case can then be supplied to an XOR module, to which multiple reference sampling values output by a reference buffer are also transmitted simultaneously and which compares the signal sampling values and the reference sampling values to each other. If the signal output by the limiter and the reference signal to be used for comparison are sampled with the same sampling clock signal(s) and synchronization is effected in the buffers in the same way and to the same slower internal clock domain, the chronological order of the reference signal sampling matches that of the limited signal being observed.

The device in accordance with the disclosed embodiments can be characterized accordingly in that the at least one signal buffer, advantageously an output of this, is connected to an input of the XOR module and that the at least one reference buffer, again advantageously on the output side, is connected to another input of the XOR module.

If two or more signal buffers are present, then these are all advantageously connected to the one input of the XOR module. If two or more reference buffers are present, then these are all advantageously connected to the other input of the XOR module.

It further possible for at least one galvanic isolation to be provided between the amplitude modulator and the demodulator. The—or in the case of multiple, the respective—galvanic isolation comprises or is constituted by at least one pair of coupling capacitors in particular. In the case of a phase modulation converter, it has been found that galvanic isolation of the signal path can easily be achieved capacitively at almost any point, which represents a considerable advantage. For example, a galvanic isolation, or at least one coupling capacitor of the same, can be provided between the amplitude modulator and a filter downstream of this or the adder. Alternatively or additionally, a galvanic isolation, or at least one coupling capacitor of the same, can also be located between the adder and the limiter. Again alternatively or additionally, a galvanic isolation, or at least one coupling capacitor of the same, can be provided between the limiter and the demodulator.

In a further embodiment, at least one signal processing module is provided. This is then connected upstream in particular of the at least one phase modulation converter. It is preferable that the at least one signal processing module comprises at least one resistor and/or at least one diode, particularly a Zener diode, and/or at least one transistor.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

Further advantages and characteristics of the present invention are explained below with reference to the following description and with reference to the enclosed drawings, in which:

FIG. 1 is an of a schematic illustration of an exemplary embodiment of a device for converting an analog input signal into a digital output signal in accordance with the invention;

FIG. 2 is an enlarged, schematic illustration of a clock generator, XOR module, integrator, and other components of the demodulator of the device of FIG. 1;

FIG. 2 is an enlarged, schematic illustration of a clock generator, XOR module, integrator, and other components of a demodulator for the use of four sampling clock signals in accordance with an alternative embodiment;

FIG. 4 is an enlarged illustration of the three clock generation blocks of the clock generator of the device of FIG. 1; and

FIG. 5 is a flowchart of the method in accordance with the invention.

### DETAILED DESCRIPTION OF THE EXEMPLARY EMBODIMENTS

Identical or similar elements and components are provided with the same reference signs in the figures.

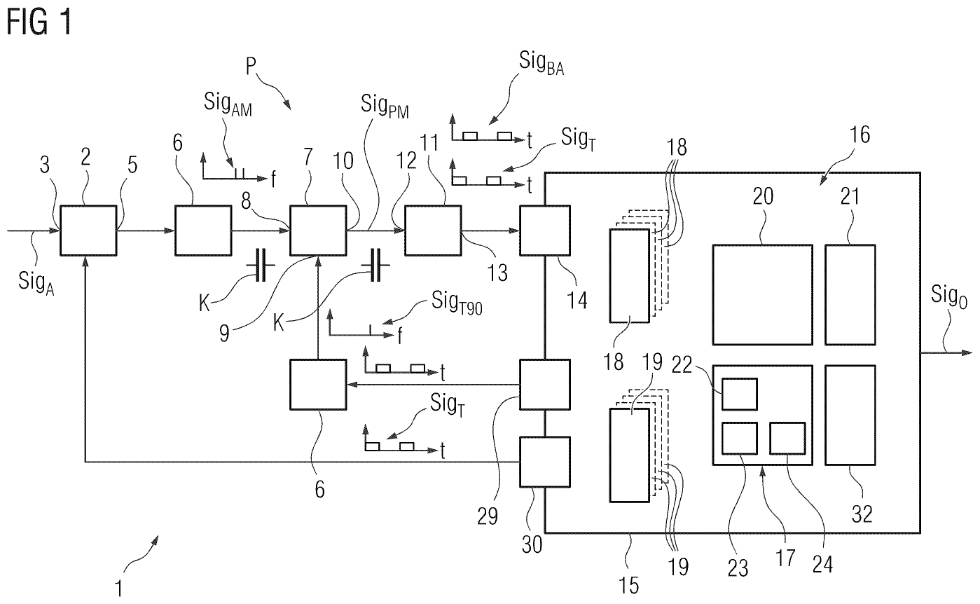

FIG. 1 shows a schematic block diagram of an exemplary embodiment of a device 1 in accordance with the invention for converting an analog input signal Siga into a digital output signal Sig_{O}, which is configured as a phase modulation converter.

The device 1 accordingly comprises an amplitude modulator 2 with carrier suppression, to which the analog signal Siga to be converted is supplied to an input 3. The amplitude modulator 2 is configured to obtain a carrierless amplitude-modulated signal Sig_{AM} from the analog input signal Siga, which is transmitted to the following stages via two differential lines. It should be noted that the figures do not show both lines separately for the differential transmission, but rather only one line for purposes of clarity. The amplitude modulator 2 can be, for example, a switch modulator or a ring modulator. A switch modulator can comprise or be constituted by at least one in particular digital switch and/or at least one mechanical relay and/or at least one reed relay and/or at least one MEMS switch.

At a second input 4, a rectangular or sinusoidal carrier signal Sig_{T} is supplied to the amplitude modulator 2, where the generation of this signal is explained in more detail below. The amplitude-modulated signal Sig_{AM} emerges from output 5 of the amplitude modulator 2 as a differential signal.

The amplitude-modulated signal Sig_{AM} then passes an analog filter 6 downstream of the amplitude modulator 2 and is supplied in turn to a downstream adder 7 of the device 1 via its input 8. At a further input 9, a further rectangular or sinusoidal carrier signal Sig_{T90} is supplied to the adder 7, which has a phase offset of 90° to the sinusoidal carrier signal Sig_{T}. By adding the carrierless amplitude-modulated signal Sig_{AM} and the sinusoidal carrier signal Sig_{T90}, a phase-modulated signal Sig_{PM} with interference amplitude modulation is obtained.

The signal Sig_{PM} is output at an output 10 of the adder 7 and is supplied to a limiter 11 via its input 12. The limiter 11 is also configured to suppress interference amplitude modulation in the signal Sig_{PM}. The obtained signal Sig_{BA}, which is also referred to as the limited signal, emerges at output 13 of the limiter 11.

The signal Sig_{BA} now carries the modulation in zero crossings at different times in comparison to the 90° carrier signal Sig_{T90} or the suppressed carrier signal Sig_{T}. This is represented purely schematically in FIG. 1 at the top right of the limiter 11. The signal Sig_{BA} (top), the signal Sig_{T} (bottom), and the temporal offset t are each shown in a graph over time. The amplitude of the signal Sig_{BA} fluctuates between 0 and 1, i.e., a digital signal in the amplitude has been obtained.

The limited signal Sig_{BA} is supplied to an input 14 of a digital circuit part 15, which is used for demodulating the signal Sig_{BA} and for other optional purposes. It should be noted that even if FIG. 1 shows no other components between the limiter 11 and the digital circuit part 15, this does not preclude such components from being present. In other words, the limited signal Sig_{BA} can be supplied to the digital circuit part 15 directly or also via other components, which can also require further processing of the signal.

It should also be noted that a coupling capacitor K can be provided in each case between the analog filter 6 and the analog adder 7, as well as between the adder 7 and the limiter 11, which is indicated accordingly in FIG. 1. The pair of coupling capacitors K are used for galvanic isolation or form such, which, in the case of a phase modulation converter 1, can be provided very easily and at almost any position in the signal path P up to the digital circuit part 15, which represents a considerable advantage of the phase modulation converter 1.

The digital circuit part 15 can comprise at least one Field-Programmable Gate Array (FPGA) and/or Application-Specific Integrated Circuit (ASIC) or can be formed by at least one FPGA and/or ASIC. In the exemplary embodiment represented here, the digital circuit part is constituted by an FPGA 15.

A demodulator 16 of the device 1 is implemented on the FPGA 15, which can be used for digital demodulation of the limited signal Sig_{BA}. The demodulator 16 can also be referred to as a digital demodulator.

Various steps occur during demodulation, including sampling of the signal Sig_{BA} via at least one sampling clock signal CLK0, CLK1, CLK2, CLK3, comparison with a reference signal Sig_{RF} that has likewise been sampled with the at least one sampling clock signal, and integration of the comparison. More details are provided below on the generation of the reference signal Sig_{RF} and the comparison.

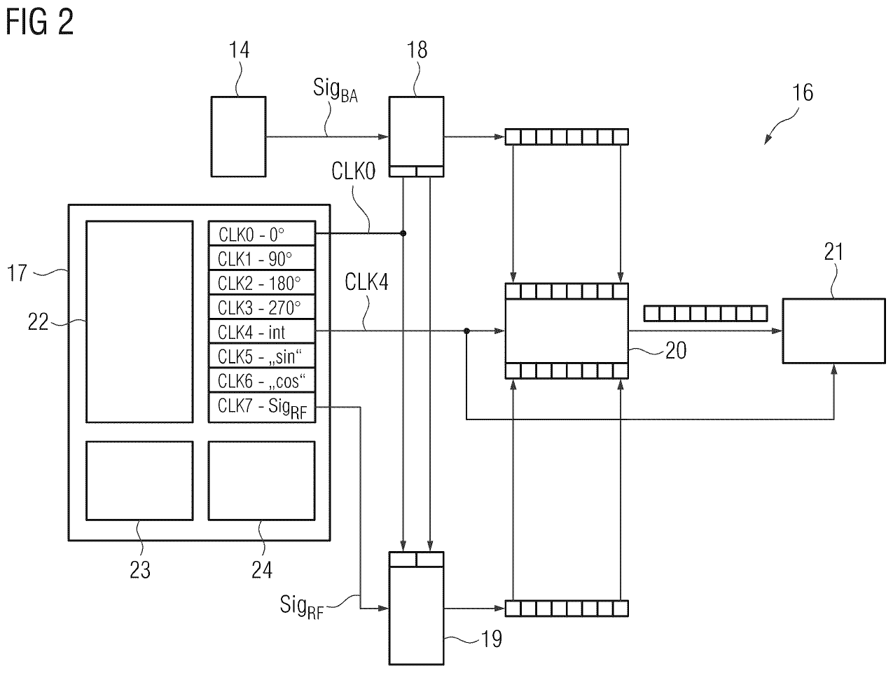

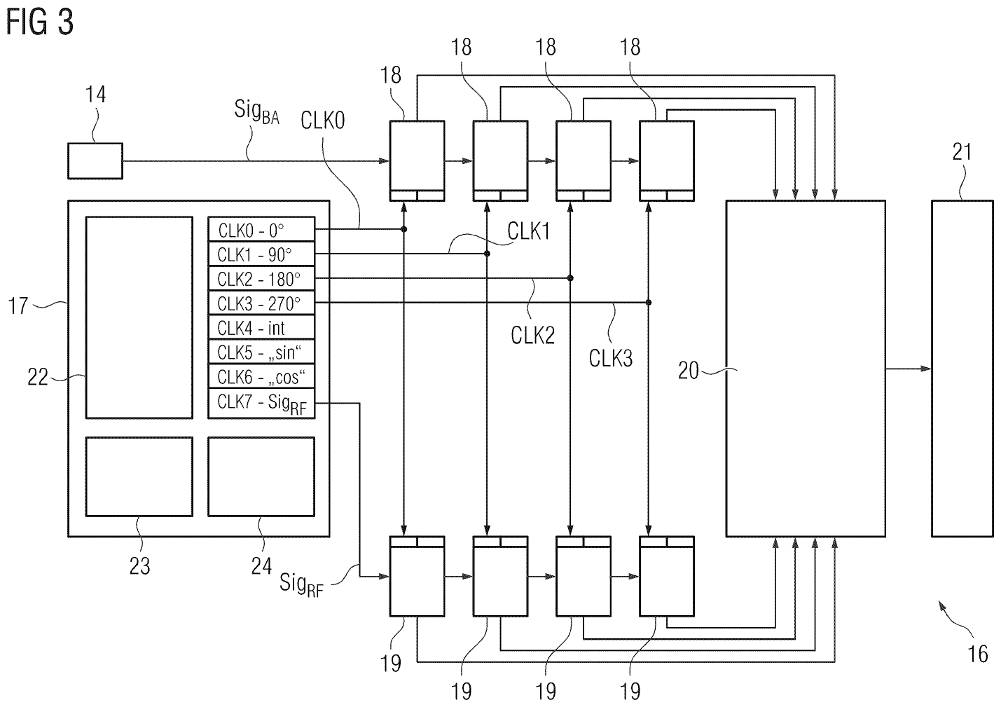

FIG. 2 includes a schematic block illustration of digital demodulation using the demodulator 16, namely in the case that sampling is effected with one sampling clock signal CLK0. FIG. 3 shows an alternative exemplary embodiment using multiple sampling clock signals for the sampling, here using four sampling clock signals CLK0, CLK1, CLK2, CLK3, for example.

The demodulator 16 comprises one clock generator 17 and at least one buffer 18 for the limited signal Sig_{BA}, which is preferably constituted by a FIFO buffer and is referred to here as a signal buffer 18. Moreover, at least one further buffer 19 is provided for the reference signal Sig_{RF}, which is likewise preferably configured as a FIFO buffer and is referred to as the reference buffer 19 to differentiate it from the buffer 18 for the signal Sig_{BA}. It should be noted that, despite these different names, the at least one signal buffer 18 and the at least one reference buffer 19 can be configured in an identical manner and, in the present invention, are configured in an identical manner.

The number of signal buffers 18 advantageously tallies with the number of reference buffers 19 and each correspond to the number of sampling clock signals CLK0, CLK1, CLK2, CLK3 that have been used. The demodulator 16 shown in FIG. 2 thus comprises precisely one signal buffer 18 and precisely one reference buffer 19.

FIG. 3 shows, for example, that four sampling clock signals CLK0, CLK1, CLK2, CLK3 can be used to sample the limited signal Sig_{BA} and the reference signal Sig_{RF} simultaneously. The demodulator 16 from FIG. 3 accordingly comprises four, preferably identical, signal buffers 18 and four, preferably identical, reference buffers 19. For reasons of clarity, the buffers 18, 19 in FIG. 1 are represented one after the other, and the foremost buffer 18, 19 is drawn with a solid line, while the buffers 18, 19 behind are drawn with a dotted line, in order to show that these can optionally be present in addition.

An XOR module 20, which can comprise an XOR gate or be constituted by such, is downstream of the buffers 18, 19 and connected to the outputs of the buffers 18, 19. Specifically, the output of the at least one signal buffer 18 is connected to an input of the XOR module 20, and the output of the at least one reference buffer 19 is connected to the other input of the XOR module 20, so that the output values can be transmitted to this and compared. In the exemplary embodiment in FIG. 3, the outputs of all four signal buffers 18 are connected to the one input of the XOR module 20, and the outputs of all four reference buffers 19 are connected to the other input of the XOR module 20.

Additionally, an integrator 21 downstream of the XOR module 20 is present, which can be used to integrate the values output by the XOR module 20.

In the exemplary embodiment represented in FIGS. 2 and 3, the clock generator 17 of the demodulator 16 comprises a total of three clock blocks 22, 23, 24. A total of seven clock signals CLK0, CLK1, CLK2, CLK3, CLK4, CLK5, CLK6, CLK7 are generated using these three clock blocks 22, 23, 24, including the sampling clock signals CLK0 (FIG. 2) or CLK0, CLK1, CLK3 (FIG. 3) used for the sampling. It should be noted that the clock blocks 22, 23, 24 can also be referred to as clock modules.

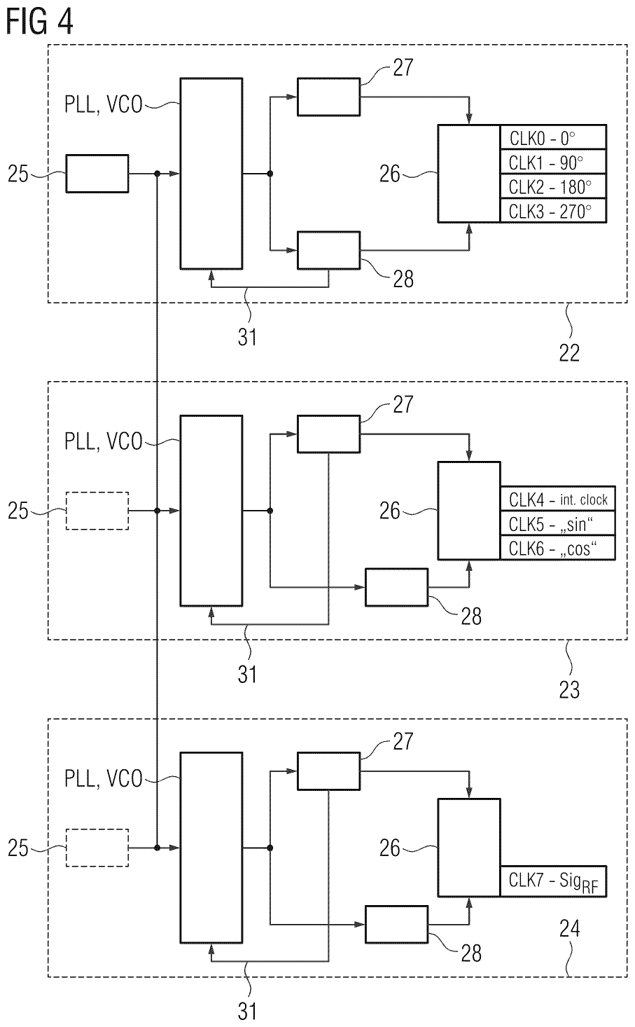

Each of the clock blocks 22, 23, 24 comprises a phase-locked loop PLL with a voltage-controlled oscillator VCO. The internal structure of the three clock blocks 22, 23, 24 is shown in FIG. 4—again heavily simplified and purely schematically. Here, the phase-locked loop PLL with the voltage-controlled, internal oscillator VCO of the respective clock block 22, 23, 24 is represented in simplified form as a block element.

The voltage-controlled, internal oscillator VCO of each clock block 22, 23, 24 is adjusted to an external reference signal by an external clock source 25, which can be constituted, for example, by a quartz resonator, with a correspondingly programmed factor to a higher internal frequency f_{VCO}. The three clock blocks 22, 23, 24 can be supplied by the same external clock source 25, which does not have to be the case, however.

The clock blocks 22, 23, 24 can, for example, be constituted by a mixed-mode clock manager (MMCM) module or block, or can comprise such a module or block. The manufacturers Xilinx or AMD, for example, offer FPGAs with such modules or blocks.

Each of the clock blocks 22, 23, 24 include multiple clock outputs, which are indicated in FIG. 4 by a block element with the reference number 26. Each clock output can accept various distributors—and thus frequencies—and various permanently defined phase positions. All clocks are thereby derived from f_{VCO}. In addition to the block element 26 representing the clock outputs, the clock signals CLK0, CLK1, CLK2, CLK3, CLK4, CLK5, CLK6, CLK7 generated and output by the respective clock block 22, 23, 24 are included in the exemplary illustrated embodiment. The corresponding numbering CLK0 to CLK7 is also used in FIGS. 2 and 3, as well as arrows for their specific use, which will be explained below. Each clock block 22, 23, 24 or its voltage-controlled oscillator VCO has both phase-locked taps 27 and at least one phase-variable tap 28. The phase-variable tap 28 allows the phase position to be divided into fine steps. In the embodiment illustrated here, the phase position can be divided into 56 steps, i.e., into steps of 360°/n, where n=56. The number of 56 steps should be understood as an example.

Clock block 22 is used to provide the fast sampling clocks, i.e., sampling clock signals for sampling both the limited signal Sig_{BA} and the reference signal Sig_{RF}. In the example illustrated in FIG. 2, this is sampling clock signal CLK0, while that illustrated in FIG. 3 it is sampling clock signals CLK0, CLK1, CLK2, CLK3.

256 MHz is given purely as an example for a frequency of the fast sampling clock signals CLK0, CLK1, CLK2, CLK3 used for sampling, which is derived from f_{VCO} and can, for example, be 1024 MHz. It should be understood other frequencies are possible. The frequency of the (respective) sampling clock signal CLK0, CLK1, CLK2, CLK3 is advantageously at least one order of magnitude higher, preferably two orders of magnitude higher, than the modulator frequency of the amplitude modulator 2.

The second clock block 23 is used to generate slow internal signals. In the illustrated exemplary embodiment, these are generated by clock signals CLK4, CLK5, and CLK6. CLK4 is a slower internal clock that is 32 MHz here, which should again be understood as an example and which is used for the buffer 18, 19, the XOR module 20, and the integrator 21, which is indicated by corresponding arrows in FIG. 2. CLK5 corresponds to a rectangular or sinusoidal signal. CLK6 to a signal shifted by 90° to the rectangular or sinusoidal signal, i.e., particularly a cosine signal. The rectangular or sinusoidal signal is output via an output 29 of the FPGA 15 toward the adder 7, in order to obtain Sig_{T90} and supply it to the input 9 of the adder 7. The cosine signal as Sig_{T} is output via an output 30 of the FPGA 15 toward the amplitude modulator 2, specifically its input 4. It should be noted that there is another analog filter 6 between the output 29 of the FPGA 15 and the input 9 of the adder 7. This filter is not marked between the output 30 of the FPGA 15 and the input 4 of the amplitude modulator 2, but this does not preclude such a filter being present.

The third clock block 24 is used to generate CLK7, which corresponds to the reference signal Sig_{RF} or is used to generate it. This is a purely internal signal, which does not leave the FPGA 15.

The three clock blocks 22, 23, 24 can largely match in terms of their structure. A difference between clock block 22 and blocks 23 and 24 does arise, however, because the feedback path 31 of the phase-locked loop (PLL) or of its voltage-controlled oscillator VCO is connected to the phase-variable tap 28 of the voltage-controlled oscillator VCO, while the feedback path 31 is connected to a phase-locked tap 27 in the case of clock modules 23 and 24 (cf. FIG. 4).

When the device is operated, in the case of FIG. 2, the one signal buffer 18 is used for sampling the limited signal Sig_{BA} with the fast sampling clock signal CLK0, or in the case of FIG. 3 the four signal buffers 18 are used for sampling the limited signal Sig_{BA} with the four fast sampling clock signals CLK0, CLK1, CLK2, CLK3 that have a constant phase shift between them, as well as for synchronizing to the slower internal clock domains. The limited signal Sig_{BA} is supplied to the (respective) signal buffer 18 on the input side for the sampling. The (respective) signal buffer 18 obtains both one of the fast sampling clock signals CLK0-CLK3 for sampling, which comes from clock block 22, and also the slower internal clock signal CLK4, which is used for synchronizing with the (respective) signal buffer 18, that of the clock block 23. It is should be noted that in FIG. 3 for use of the multiple sampling clock signals CLK0-CLK3 and associated buffers 18, 19, for purposes of clarity, the arrows to the slower internal clock CLK4 are not additionally included in the drawing.

The (respective) signal buffer 18 has one input with a bit width of 1 and one output with a bit width of 8. The ratio of the bit widths from the input to the output of the (respective) signal buffer 18 is selected analogously to the ratio of the clocks CLKi/CLK4, where i=0, 1, 2, 3, or vice versa. In the example described here, CLKi/CLK4=256 MHz/32 MHz=8, where i=0, 1, 2, 3.

Invariably, if 8 sampling values are “accrued” in one signal buffer 18, then these multiple values are output by the signal buffer 18, i.e., to the XOR module 20. They are output with the slower clock of CLK4, i.e., 32 MHz here. It can also be stated that the (respective) signal buffer 18 supplies as the output the “sampled” digital limited signal Sig_{BA} in the correct chronological sequence.

The above applies fully analogously to the (respective) reference buffer 19, with the difference that this is not supplied the limited signal Sig_{BA}, but rather the reference signal Sig_{RF} for sampling with the (respective) fast sampling clock signal CLK0-CLK3 and for synchronizing to CLK4, as indicated schematically by the associated arrows in FIGS. 2 and 3.

Thus, the “sampled” digital reference signal is obtained from the (respective) reference buffer 19, which is clocked with the same clock signal CLK0 or with the same clock signals CLK0, CLK1, CLK2, CLK3. Thus, the chronological sequence matches the “sampled” limited signal Sig_{BA}, which is obtained from the signal buffer(s) 18.

In the embodiment of FIG. 3 with the four sampling clock signals CLK0-CLK3, each signal buffer 18 outputs a different part of the signal. Each CLK sampling domain supplies one data block. The reference signal Sig_{RF} is appropriately “sampled” in the same domain. A comparison is then possible “on a block basis” in the XOR module 20.

To achieve an increased resolution, it is provided in the sampling that the phase position of the one sampling clock signal CLK0 (FIG. 2) or the multiple sampling clock signals CLK0-CLK3 (FIG. 3), which are used for sampling the limited signal Sig_{BA} and the reference signal Sig_{RF}, is dynamically altered. The feedback path 31 of the clock block 22 for producing the fast sampling clock signals CLK0-CLK3 is, as mentioned above, connected to the phase-variable tap 28 of the voltage-controlled oscillator VCO for this purpose.

The phase position of the signal supplied back via the feedback path 31 to the voltage controlled oscillator VCO is continuously or repeatedly altered. This is preferably effected cyclically, for example, every couple of microseconds, for instance, every 42 microseconds. The shift of the phase position is effected in each case in steps of 360°/56 and in the same direction. A logic 32 is provided (cf. FIG. 1), which is preferably implemented on the FPGA 15, which also comprises or formed the demodulator 16 and which realizes the corresponding control for the dynamic phase position alteration of the sampling clock signals. The logic 32 can be an element of the demodulator 16.

As the multiple sampling clock signals CLK0, CLK1, CLK2, CLK3 in the exemplary embodiment of FIG. 3 are all generated from the output signal of a voltage-controlled oscillator VCO of the clock block 22, the repeated alteration of the phase position of the feedback signal results in a repeated alteration of the phase position of all the sampling clock signals CLK0, CLK1, CLK2, CLK3 used for the sampling synchronously and in equally large steps.

Due to the stepping of the feedback signal via the feedback path 31, the phase position of all CLK outputs of the clock module 22 alter synchronously with each phase step of the voltage-controlled oscillator VCO. The individual sampling clock signals CLK0, CLK1, CLK2, CLK3 can also have a constant shift between them of 90°. In the described instance, a phase step corresponds to

$${t}_{STEP} = 1 / ( 768 MHz * 56 ) = 1 / 43.008 GHz = 23.25 ps .$$

The 256 MHz sampling clocks CLK0-CLK3 with a shift between them of 90° only have to suppress a phase difference of

$${t}_{diff} = 1 / ( 256 MHz * 4 ) = 976.56 ps$$

to cover all possible discrete sampling points via fine-step phase stepping. In the FPGA 15, 42 (976.56 ps/23.25 ps) cycles of the modulator frequency are added.

The calculated resolution results in

$$log 2 ( 90 ° / 360 ° * 43008 MHz / 1 MHz ) = 13.39 bits$$

without altering the frequency of the amplitude modulator 2.

The data rate reduces from 1 MHz to 1 MHz/42=23.8 KHz.

Without the dynamic phase shift, a calculated resolution of

$$log 2 ( 90 ° / 360 ° ⋆ 4 * 256 MHz / 1 MHz ) = 8 bits$$

would result in contrast.

Following the fast sampling and synchronization, the XOR module 20 downstream of the buffers 18, 19 is used to determine the points in time at which the limited signal Sig_{BA} and the reference signal Sig_{RF} differ. The subsequent integration via the integrator 21 produces the value to be converted, which is output by the FPGA 15 as Sig_{O} (cf. FIG. 1).

Integration is advantageously maintained until the dynamic alteration of the phase position of the sampling clock signals CLK0, CLK1, CLK2, CLK3 described above is effected over an angle range of 360°/m, where m corresponds to the number of sampling clock signals used for sampling the limited signal Sig_{BA}. The device 1 in accordance with the disclosed embodiments of the invention, particularly its demodulator 16 or an FPGA 15 of the device, can be set up accordingly.

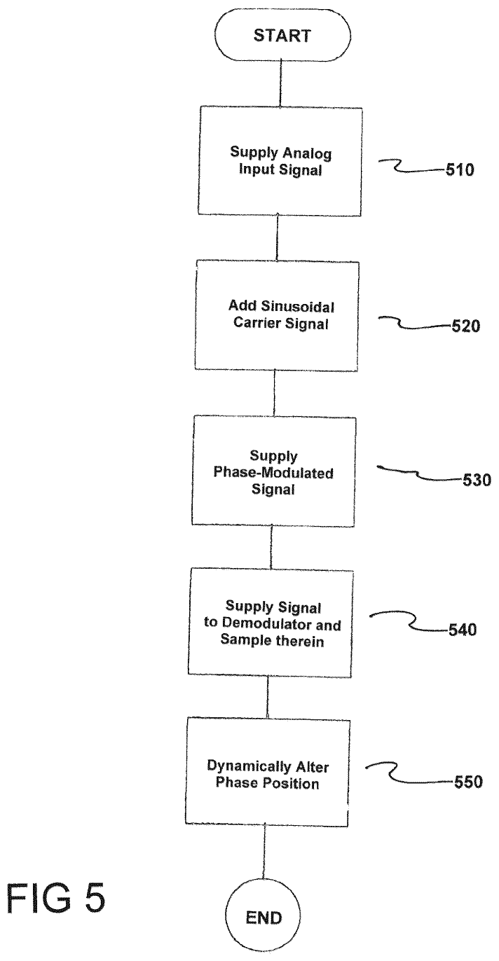

FIG. 5 is a flowchart of the method for converting an analog input signal Siga into a digital output signal Sig_{O}.

The method comprises feeding the analog input signal Siga to be converted to an input side of an amplitude modulator 2 with carrier suppression to obtain a carrierless amplitude-modulated signal Sig_{AM}, as indicated in step 530.

Next, a sinusoidal carrier signal offset by 90° Sig_{T90} is added via an adder 7 to the amplitude-modulated signal Sig_{AM} output by the amplitude modulator 2 to obtain a phase-modulated signal Sig_{PM}, as indicated in step 520.

Next, the phase-modulated signal Sig_{PM} is supplied to a limiter 11, as indicated in step 530. In accordance with the invention, the limiter 11 suppresses interference amplitude modulation in the phase-modulated signal Sig_{PM}.

Next, the signal Sig_{BA} output by the limiter (11) is supplied to a demodulator 16 and sampled therein with at least one sampling clock signal CLK0, CLK1, CLK2, CLK3, as indicated in step 540.

Next, dynamically altering a phase position of the at least one sampling clock signal CLK0, CLK1, CLK2, CLK3 is dynamically altered in predetermined steps to achieve a higher resolution, as indicated in step 550.

Although the invention has been illustrated and described in detail with the preferred exemplary embodiment, the invention is not restricted by the examples disclosed and other variations may be derived therefrom by a person skilled in the art without departing from the protective scope of the invention.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps that perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A method for converting an analog input signal into a digital output signal, the method comprising:
supplying the analog input signal to be converted to an input side of an amplitude modulator with carrier suppression to obtain a carrierless amplitude-modulated signal;
adding, via an adder, a sinusoidal carrier signal offset by 90° to the amplitude-modulated signal output by the amplitude modulator to obtain a phase-modulated signal;
supplying the phase-modulated signal to a limiter, said limiter suppressing interference amplitude modulation in the phase-modulated signal;
supplying the signal output by the limiter to a demodulator and sampling said signal therein with at least one sampling clock signal; and
dynamically altering a phase position of the at least one sampling clock signal in steps of less than 40° to achieve a higher resolution.

2. The method as claimed in claim 1, wherein the phase position of the at least one sampling clock signal is dynamically altered in equally large steps of 360°/n in each case, n being a natural number greater than or equal to 30.

3. The method as claimed in claim 1, wherein the phase position of the at least one sampling clock signal is altered at multiple successive points in time, separated from each other at equidistant intervals; and wherein at least one microsecond is provided between each separated point in time.

4. The method as claimed in claim 1, wherein the phase position of the at least one sampling clock signal is altered at least n/m times in steps of 360°/n, n being a natural number greater than or equal to 30 and m being a natural number greater than or equal to 1.

5. The method as claimed in claim 1, wherein the signal output by the limiter is sampled in the demodulator with multiple sampling clock signals each having a constant phase shift of 90° therebetween, and the phase positions of all sampling clock signals are dynamically altered to achieve a higher resolution; and wherein the phase position alteration of the multiple sampling clock signals is effected at least one of synchronously and in equally large steps of less than 40°.

6. The method as claimed in claim 1, wherein the signal output by the limiter is sampled in the demodulator with four sampling clock signals.

7. The method as claimed in claim 4, wherein m corresponds to a number of multiple sampling clock signals having a constant phase shift therebetween.

8. The method as claimed in claim 7, wherein m is four.

9. The method as claimed in one claim 1, wherein the at least one sampling clock signal is generated from an output signal of a voltage-controlled oscillator, which is an element in a phase-locked loop, and the dynamic alteration of the phase position of the at least one sampling clock signal is achieved by dynamically altering the phase position of a feedback signal for the voltage-controlled oscillator, which is tapped on an output side of the voltage-controlled oscillator and which is again supplied to the voltage-controlled oscillator, on an input side, in steps of less than 40°.

10. The method as claimed in claim 4, wherein the multiple sampling clock signals are generated from the output signal of a voltage-controlled oscillator, and the dynamic alteration of the phase position of the feedback signal results in each case in an alteration of the phase positions of all sampling clock signals synchronously and in equally large steps.

11. The method as claimed in claim 9, wherein the voltage-controlled oscillator includes at least one phase-variable tap and multiple phase-locked taps; and wherein the at least one phase-variable tap allows a 360° phase position of the voltage-controlled oscillator to be divided into n steps, n being a natural number greater than or equal to 30; and
wherein the phase-variable tap is connected to the feedback path of the voltage-controlled oscillator, such that a signal emanating from the phase-variable tap is suppliable to the oscillator again as a feedback signal, on an input side, and the phase position of the signal emanating from the phase-variable tap is dynamically altered in steps of 360°/n, n being greater than or equal to 40.

12. The method as claimed in claim 1, wherein within the demodulator an area overlap between the signal output by the limiter and supplied to the demodulator and a reference signal is calculated over multiple cycles.

13. The method as claimed in claim 1, wherein the signal output by the limiter supplied to the demodulator is compared in the demodulator in an XOR module bit-by-bit to a reference signal after sampling with the at least one sampling clock signal, and the output signal of the XOR module is integrated; and wherein, in each case, integration is maintained until the dynamic alteration of the phase position is effected over an angle range of 360°/m, m being a natural number corresponding to the number of sampling clock signals.

14. A device for converting an analog input signal into a digital output signal, the device comprising:
an amplitude modulator with carrier suppression, an analog input signal to be converted being suppliable to an input side of the amplitude modulator to obtain a carrierless amplitude-modulated signal;
an adder which adds a sinusoidal carrier signal offset by 90° to the carrierless amplitude-modulated signal to obtain a phase-modulated signal;
a limiter which receives the phase-modulated signal and with which interference amplitude modulation in the phase-modulated signal is suppressed;
a demodulator which receives and samples the signal output by the limiter therein with at least one sampling clock signal;
means for phase position alteration which dynamically alter the phase position of the at least one sampling clock signal in steps of less than 40° to achieve a higher resolution.

15. The device as claimed in claim 14, wherein the demodulator includes a clock generator for generating the at least one sampling clock signal;
wherein the clock generator includes at least one clock generation module, which comprises a phase-locked loop with a voltage-controlled oscillator;
wherein the voltage-controlled the oscillator includes at least one phase-variable tap and multiple phase-locked taps;
wherein the at least one phase-variable tap allows a 360° phase position of the oscillator to be divided into n steps, n being a natural number greater than or equal to 30; and
wherein the phase-variable tap is connected to the feedback path of the voltage-controlled oscillator, such that a signal emanating from the phase-variable tap is again suppliable to the voltage-controlled oscillator as a feedback signal, on an input side, and the means for phase position alteration dynamically alters the phase position of the signal emanating from the phase-variable tap in steps of 360°/n, n being greater than or equal to 40.

16. The device as claimed in claim 14, wherein the demodulator is configured to calculate an area overlap between the signal output by the limiter supplied to the demodulator and a reference signal over multiple cycles.

17. The device as claimed in claim 14, wherein the demodulator comprises at least one XOR module and at least one integrator downstream of the XOR module.

18. The device as claimed in claim 14, wherein the demodulator comprises at least one signal buffer comprising a FIFO signal buffer in which the signal sampling values, which are present due to sampling of the signal output by the limiter with the at least one sampling clock signal, can be buffered, and from which multiple signal sampling values can each be output at a lower frequency in comparison to a frequency of the at least one sampling clock signal; and
wherein the demodulator further comprises at least one reference buffer comprising a FIFO reference buffer, in which the reference sampling values, which are present due to sampling of a reference signal with the at least one sampling clock signal, can be buffered, and from which multiple reference sampling values can each be output at the lower frequency in comparison to the frequency of the at least one sampling clock signal.

19. The device as claimed in claim 16, wherein the at least one signal buffer is connected to an input of the XOR module; and wherein the at least one reference buffer is connected to another input of the XOR module.

20. The device as claimed in claim 14, further comprising:
at least one galvanic isolation arranged between the amplitude modulator and the demodulator;
wherein the at least one galvanic isolation comprises at least one pair of coupling capacitors.
